(19) United States
(12) Patent Application Publication
(10) Pub. No.: US 2010/0031996 A1
(43) Pub. Date: Feb. 11, 2010

(54) STRUCTURE AND METHOD OF MANUFACTURING THIN FILM PHOTOVOLTAIC MODULES

(76) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/250,507

(22) Filed: Oct. 13, 2008

Related U.S. Application Data
(63) Continuation-in-part of application No. 12/189,627, filed on Aug. 11, 2008.
(60) Provisional application No. 61/097,628, filed on Sep. 17, 2008.

(51) Int. Cl. H01L 31/042; B32B 37/02

(52) U.S. Cl. 136/244; 156/308.2

(57) ABSTRACT

A continuous manufacturing method to form a continuous multi-module device including a plurality of solar cell modules is provided. The continuous multi-module device can be cut into sections including a desired number of solar cell modules that can be used in solar energy applications. The number of solar cells in the desired section can be advantageously electrically connected by connecting power output wires that outwardly extend from each solar cell module. If any solar cell module malfunctions during its use, that portion may be easily removed and the remaining modules are reconnected.

### CLAIM OF PRIORITY

This application is a Continuation-in-Part of U.S. patent application Ser. No. 12/189,627, filed Aug. 11, 2008, entitled “Photovoltaic Modules with Improved Reliability,” and this application also relates to and claims priority from U.S. Provisional Application No. 61/097,628, filed Sep. 17, 2008, entitled “Method of Manufacturing Flexible Thin Film Photovoltaic Modules”, both of which are expressly incorporated herein by reference.

### BACKGROUND

1. Field of the Inventions

The aspects and advantages of the present inventions generally relate to apparatus and methods of photovoltaic or solar module design and fabrication and, more particularly, to roll-to-roll or continuous packaging techniques for flexible modules employing thin film solar cells.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Ti) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which includes a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

There are two different approaches for manufacturing PV modules. In one approach that is applicable to thin film CdTe, amorphous Si and CIGS technologies, the solar cells are deposited or formed on an insulating substrate such as glass that also serves as a back protective sheet or a front protective sheet, depending upon whether the device is “substrate-type” or “superstrate-type”, respectively. In this case the solar cells are electrically interconnected as they are deposited on the substrate. In other words, the solar cells are monolithically integrated on the single-piece substrate as they are formed. These modules are monolithically integrated structures. For CdTe thin film technology the superstrate is glass which also is the front protective sheet for the monolithically integrated module. In CIGS technology the substrate is glass or polyimide and serves as the back protective sheet for the monolithically integrated module. In monolithically integrated module structures, after the formation of solar cells which are already integrated and electrically interconnected in series on the substrate or superstrate, an encapsulant is placed over the integrated module structure and a protective sheet is attached to the encapsulant. An edge seal may also be formed along the edge of the module to prevent water vapor or liquid transmission through the edge into the monolithically integrated module structure.

In standard Si module technologies, and for CIGS and amorphous Si cells that are fabricated on conductive substrates such as aluminum or stainless steel foils, the solar cells are not deposited or formed on the protective sheet. They are separately manufactured and then the manufactured solar cells are electrically interconnected by stringing them or shingling them to form solar cell strings. In the stringing or shingling process, the (+) terminal of one cell is typically electrically connected to the (−) terminal of the adjacent device. For the Group IBIIIAVIA compound solar cell shown in FIG. 1, if the substrate 11 is conductive such as a metallic foil, then the substrate, which is the bottom contact of the cell, constitutes the (+) terminal of the device. The metallic grid (not shown) deposited on the transparent layer 14 is the top contact of the device and constitutes the (−) terminal of the cell. In shingling, individual cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another. The solar modules are constructed using various packaging materials to mechanically support and protect the solar cells in them against mechanical damage. The most common packaging technology involves lamination of circuits in transparent encapsulants. In a lamination process, in general, the electrically interconnected solar cells are covered with a transparent and flexible encapsulant layer which fills any hollow space among the cells and tightly seals them into a module structure, preferably covering both of their surfaces. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which forms resistance to moisture transmission into the module package. The nature of the protective shell determines the amount of water that can enter the package. The protective shell includes a front protective sheet and a back protective sheet and optionally an edge sealant that is at the periphery of the module structure (see for example, published application WO/2003/050891, “Sealed Thin Film PV Modules”). The top protective sheet is typically glass which is water impermeable. The back protective sheet may be a sheet of glass or a polymeric sheet such as TEDLAR® (a product of DuPont). The back protective polymeric sheet may or may not have a moisture barrier layer in its structure such as a metallic film like an aluminum film. Light enters the module through the front protective sheet. The edge sealant, which is presently used in thin film CdTe modules with glass/glass structure, is a moisture barrier material that may be in the form of a viscous fluid which may be dispensed from a nozzle to the peripheral edge of the module structure or it may be in the form of a tape which may be applied to the peripheral edge of the module structure. The edge sealant in Si-based modules is not between the top and bottom protective sheets but rather in the frame which is attached to the edge of the module. Moisture barrier characteristics of edge seals used for Si-based modules are not adequate for CIGS based modules as will be discussed later.

Flexible module structures may be constructed using flexible CIGS or amorphous Si solar cells. Flexible modules are light weight, and unlike the standard glass based Si solar modules, are un-breakable. Therefore, packaging and transportation costs for flexible modules are much lower. However, packaging of flexible structures are more challenging. Glass handling equipment used in glass based PV module manufacturing are fully developed by many equipment suppliers. Handling of flexible sheets cannot be carried out using such standard equipment. The flexible sheets that constitute the various layers in the flexible module structure may be cut into sizes that are close to the desired area of the module, and then the standard module encapsulation procedures may be carried out by handling and moving these pieces around. A more manufacturing friendly approach for flexible module manufacturing is needed to increase the reliability of such modules and reduce their manufacturing cost. Some prior art processing approaches for flexible amorphous Si based device fabrication are described in U.S. Pat. Nos. 4,746,618, 4,773,944, 5,131,954, 5,968,287, 5,457,057 and 5,273,608.

### SUMMARY

The aspects and advantages of the present inventions generally relate to apparatus and methods of photovoltaic or solar module design and fabrication and, more particularly, to roll-to-roll or continuous packaging techniques for flexible modules employing thin film solar cells.

### BRIEF DESCRIPTION OF THE DRAWINGS

FIG. 1 is a schematic view a thin film solar cell;

FIG. 2A is a schematic cross sectional view of a flexible thin film solar module;

FIG. 2B is a schematic top view of the module of FIG. 2A;

FIGS. 3A-3F are schematic views of an embodiment of manufacturing of a continuous packaging structure of the present invention including a plurality of module structures;

FIGS. 4A-4B are schematic views of transforming the continuous packaging structure into a continuous multi-module power device including a plurality of solar modules;

FIG. 5 is a schematic side view of a solar module of the present invention;

FIGS. 6A-6B are schematic views of an embodiment of manufacturing monolithically integrated multi-module power supplies; and

FIG. 7 is a schematic view of a roll to roll system to manufacture flexible photovoltaic modules of the present invention.

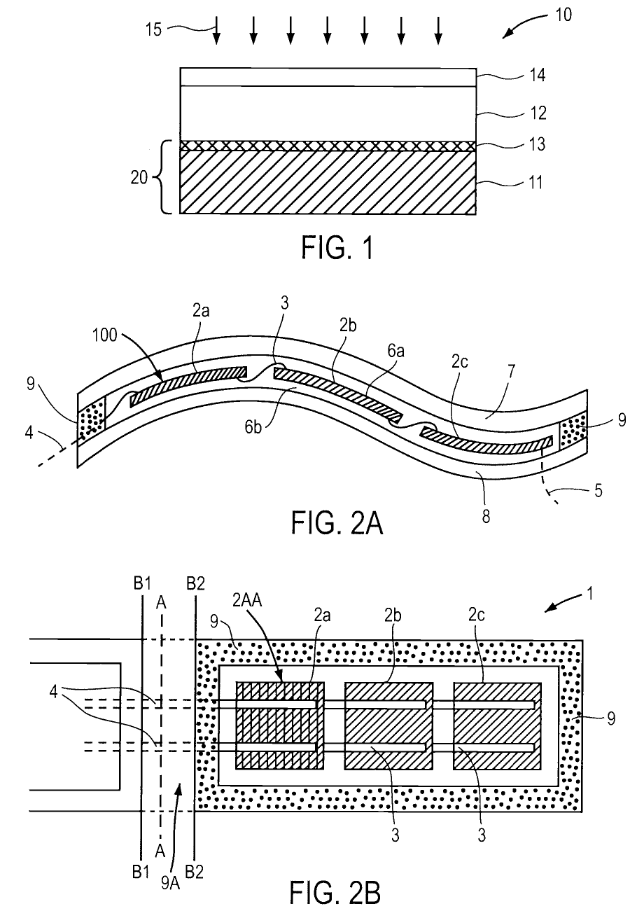

### DETAILED DESCRIPTION OF THE PREFERRED EMBODIMENTS

The preferred embodiments described herein provide methods of manufacturing flexible photovoltaic modules employing thin film Group IBIIIAVIA compound solar cells. The modules each include a moisture resistant protective shell within which flexible interconnected solar cells or cell strings are packaged and protected. The protective shell comprises a moisture barrier top protective sheet through which the light may enter the module, a moisture barrier bottom protective sheet, a support material or encapsulant covering at least one of a front side and a back side of each cell or cell string. The support material may preferably be used to fully encapsulate each solar cell and each string, top and bottom. The protective shell additionally comprises a moisture sealant that is placed between the top protective sheet and the bottom protective sheet along the circumference of the module and forms a barrier to moisture passage from outside into the protective shell from the edge area along the circumference of the module. Unlike in amorphous Si based flexible modules, the top protective sheet and the bottom protective sheet of the present module have a moisture transmission rate of less than 10⁻³ gm/m²/day, preferably less than 5×10⁻⁴ gm/m²/day. Additionally, unlike in flexible amorphous Si modules, there is a moisture sealant along the circumference of the module with similar moisture barrier characteristics.

In one embodiment, the present invention specifically provides a continuous manufacturing method to form a continuous packaging structure including a plurality of solar cell modules on elongated protective sheet bases. A moisture barrier frame is first applied on the elongated protective sheet having pre designated module areas. The moisture barrier frame is a moisture sealant (with transmission rate of <10⁻³ gm/m²/day, or moisture breakthrough time of at least 20 years through the seal) which may be applied on the elongated protective sheet as a tape, gel or liquid. The walls of the moisture barrier frame surround the borders of each of the plurality of designated module areas and form a plurality of cavities defined by the walls of the moisture barrier frame and the designated module areas. The walls of the moisture barrier frame include side walls and divider walls. The side walls may form side walls of the plurality of cavities. Divider walls separate individual cavities from one another by forming adjoining walls between two cavities. Solar cell strings are placed into each of the cavities and supported by a support material filling each cavity. The strings in the adjacent cavities are not electrically connected to one another. A pair of power output wires or terminals is extended from the strings to the outside through the side walls. To complete the assembly, a second support material is placed over the strings and a second elongated protective sheet is placed over the support material and the moisture barrier frame to enclose the plurality of cavities, thereby forming the plurality of solar cell modules. After the continuous packaging structure is completed in a continuous manner, it is laminated to form a continuous multi-module device including a plurality of laminated solar cell modules. The continuous multi-module device can be cut into sections including a desired number of laminated solar cell modules that can be used in solar energy production applications. The laminated solar cell modules in each section can also be advantageously electrically connected by connecting power output wires that outwardly extend from each solar cell module. If any solar cell module malfunctions during the application, that malfunctioning portion may be easily removed and the remaining modules are reconnected for the system to continue performing. Such removal may be only electrical in nature, i.e. the failed module is electrically taken out of the circuit by simply disconnecting its power output wires. It is also possible to physically remove the failed module by cutting it out along the two divider walls on its two sides without negatively impacting the moisture sealant nature of the divider walls.

Reference will now be made to the drawings wherein like numerals refer to like parts throughout. FIG. 2A shows the cross section of an exemplary flexible module 1. FIG. 2B is a top view of the same module. The exemplary flexible module 1 is an overly simplified one comprising only three cells 2a, 2b and 2c forming a string. In reality, many more cells and cell strings are used. The three cells 2a, 2b and 2c are interconnected using conductor wires 3 to form the cell string 2AA and terminal wires 4 extend to outside the perimeter formed by the top protective sheet 7 and the bottom protective sheet 8. It should be noted that in manufacturing, the wires 4 can be extended to outside the module by cutting the continuous packaging structure along line A-A as shown in FIG. 2B, and then removing material 9a that exists within the area between lines B1 and B2, thereby leaving the wires 4 extending outside the perimeter of the module. Alternately wires 4 may be joined together within the package and then only a single wire (not shown) can extend outside the module. It is also possible to take the terminal wire from the back side of the module 1 as shown in the case of terminal wire 5. It is, however, preferable to bring the terminal wires through the moisture sealant 9 in a sealed manner. If a terminal is taken out through the top protective sheet 7 or the bottom protective sheet 8, moisture may enter the module structure through the hole or holes opened for the terminals to go through. Therefore such holes would have to be sealed against moisture permeation. The cell string 2AA is covered with a top support material or encapsulant 6a and a bottom encapsulant 6b. The top encapsulant 6a and the bottom encapsulant 6b are typically the same material but they may be two different materials that melt together and surround the cell string 2AA top and bottom. The top protective sheet 7 which is transparent and resistive to moisture permeation, the bottom protective sheet 8 which is resistive to moisture permeation, and a moisture sealant 9 along the edge of the module form a protective shell 100, which is filled with the cell string 2AA, the top encapsulant 6a and the bottom encapsulant 6b. It should be noted that the thicknesses of the components shown in the figures are not to scale.

The following part of the description includes an embodiment describing how a flexible module structure such as the one shown in FIGS. 2A and 2B, as well as a modification of that flexible module structure as it relates to the terminal wires that extend outside a perimeter of the flexible module structure through the moisture sealant, may be fabricated in a continuous manner using continuous manufacturing techniques such as in-line or roll-to-roll process.

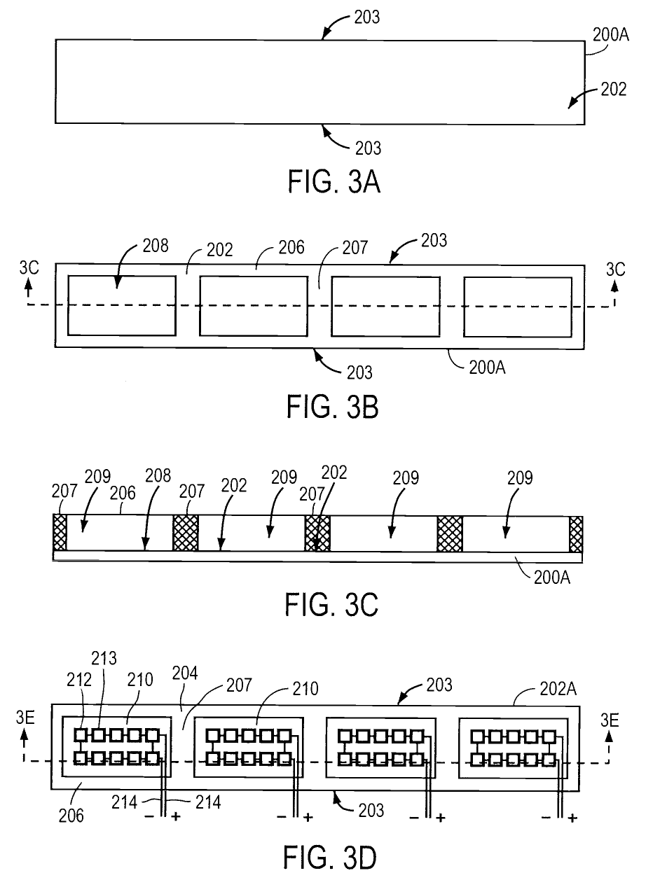

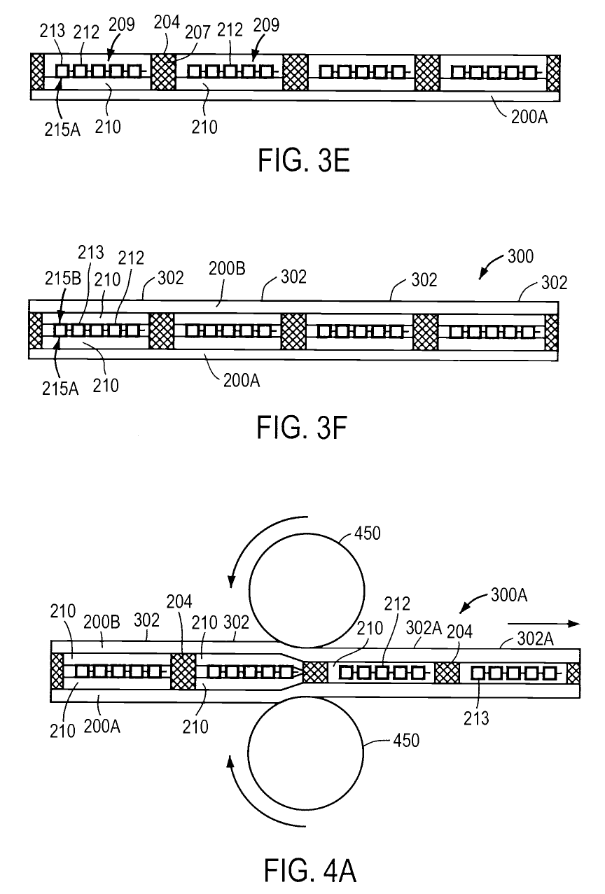

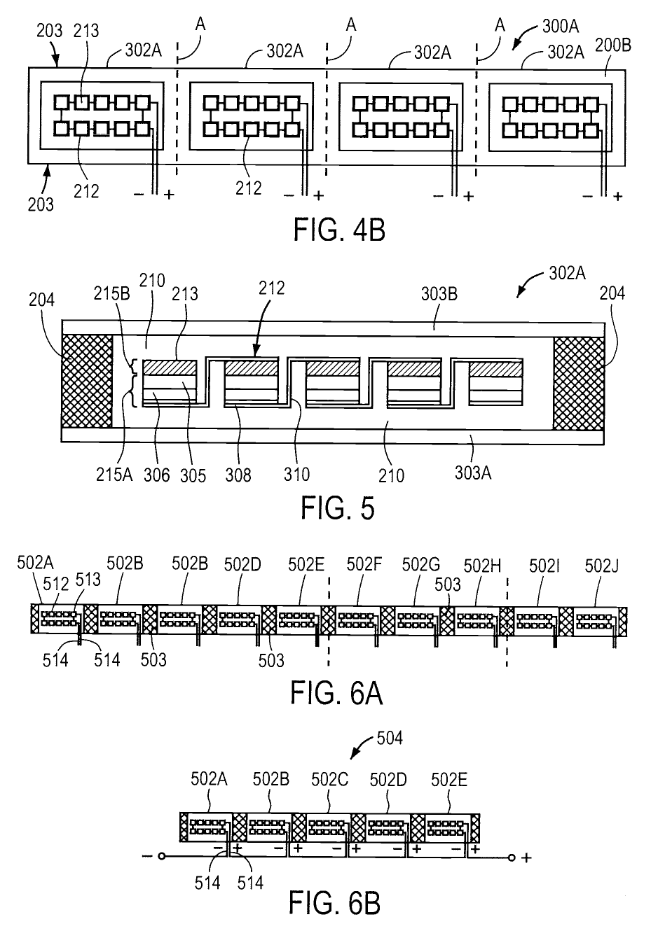

As shown in FIGS. 3A-4B, during the roll-to roll or continuous process of the invention, an initial component such as an elongated top protective sheet 200A may be first provided in a continuous or stepwise manner from a supply roll of a roll-to-roll module manufacturing system, and travels through a number of process stations, which add other components of the modules over the elongated protective sheet to manufacture a continuous packaging structure including a plurality of solar cell modules. Resulting continuous multi-module device may then be rolled onto a receiving spool to form a roll, or the continuous multi-module device may be cut into smaller sections each containing one or more modules as will be explained later.

FIG. 3A shows a first step of the process during which a section of the top elongated protective sheet 200A having a back surface 202 and two edges 203 is provided. The width of the elongated protective sheet may typically be in the range of 30-300 cm. The top elongated protective sheet forms the front side or the light receiving side of the modules that will be manufactured using the process of the invention. As shown in FIG. 3B in top view and in FIG. 3C in side view, in a second process step, a moisture sealant 204 is applied on the back surface 202 of the top elongated protective sheet 200A. The moisture sealant 204 surrounds module spaces 208 and is preferably deposited along the two edges 203 of the protective sheet 200A and between the module spaces 208. The portion of the moisture sealant 204 deposited along the edges 203A of the top elongated protective sheet 200A will be called side sealant 206 or side wall and the portion of the moisture sealant disposed between the module spaces 208 or ends of the module spaces will be called divider sealant 207 or divider wall. The moisture sealant 204 may be in the form of a tape or it may be a viscous liquid that may be dispensed onto the back surface 202 of the top elongated protective sheet 200A. The module spaces 208 are the spaces on the back surface 202 that are bordered or surrounded by the moisture sealant 204 applied on the back surface 202. As shown in FIG. 3C, the side walls 206 and the divider walls 207 of the moisture sealant 204 form a plurality of cavities 209 on the top elongated protective sheet 200A. Each cavity 209 may be defined by one module space 208 and the side walls 206 and divider walls 207 that surround that module space 208. In this respect, the moisture sealant 204 may be formed as a single piece continuous frame including the side walls and the divider walls which are shaped and dimensioned according to the desired solar cell module shape and size. When such frame is applied on the back surface 202 of the top elongated protective sheet 200A, it forms the cavities 209.

As shown in FIG. 3D in top view and in FIG. 3E in side schematic view, after disposing the moisture sealant 204, support material layers 210 or encapsulants are placed over each module space 208 within the cavities 209 and then the solar cell strings 212 are placed over the support material 210 in a face-down manner. A light receiving side 215A of each solar cell 213 in each string 212 faces toward the elongated top protective sheet 200A. Electrical leads 214 or terminals of the module may preferably be taken out of the cavity 209 through the side wall 206 of the moisture sealant 204 disposed along at least one of the long edges of the elongated protective sheet 200A, in a way that the moisture sealant 204 also seals around the electrical leads 214. As shown in the figures, solar cell strings 212 include solar cells 213 that are electrically interconnected. However, the strings 212 in each of the cavities 209 are not electrically interconnected to one another, i.e. there is no electrical connection between cells in one cavity with the cells in an adjacent cavity. It is, however, possible to have such interconnections as described in the U.S. patent application with Ser. No. 12/189,627 entitled “photovoltaic modules with improved reliability” filed Aug. 11, 2008, in which a fabricated module may comprise two or more sealed compartments (e.g. the cavities 209) each containing solar cell strings.

As shown in FIG. 3F in side schematic view, in the following step, back side 215B or base of the solar cells 213 are covered with another layer of support material 210. A back elongated protective sheet 200B is placed on the moisture sealant 204 and over the support material 210 to complete the assembly of the components of a continuous packaging structure 300 having a plurality of solar cell module structures 302.

As shown in FIG. 4A, the continuous packaging structure 300 is processed in a laminator, such as a roll laminator with rollers 450 to transform it to a continuous multi-module device 300A having a plurality of solar cell modules 302A. During the lamination process, the support material 210 in each module structure 302 melts and adheres to the solar cell strings 212 and to the top and back elongated protective sheets 200A and 200B. The moisture sealant 204 also melts and adheres to the top and back elongated protective sheets 200A and 200B.

FIG. 4B shows in top view the continuous multi-module device 300A having the solar cell modules 302A after the continuous packaging structure 300 is processed in the laminator. It should be noted that in this continuous process, support materials that do not involve chemical cross linking are preferred to support materials that involve cross linking, such as EVA. The preferred support materials include silicones and thermo plastic materials that may have melting temperatures in the range of 90-150 C. The moisture sealant 204 may also be a thermo plastic that can be melted easily in a roll laminator where pressure and heat may be applied to the module structure in presence or in absence of vacuum. It should be noted that the sealant material 204 may be dispensed in liquid form or it may be in the form of an adhesive tape that adheres on the back surface 202 of the top elongated protective sheet 200A. If liquid silicone is used as the support material 210, the silicone may be dispensed onto each module area defined by the cavity 209 formed by the back surface 202 and the sealant material 204. Therefore, the back surface 202 and the sealant material 204 acts like a container to contain the liquid silicone support material 210. The silicone support material 210 may be partially cured before the cell string is placed onto it (see FIGS. 3D and 3E) so that the cell string does not sink into the liquid and touch the back surface 202 of the top elongated protective sheet 200A. For cell strings containing flexible CIGS solar cells fabricated on stainless steel substrates, it may be difficult to keep all the cells in the string lying flat on the top surface of the semi-cured silicone layer. Therefore, a series of magnets may be used under the top elongated protective sheet 200A. These magnets pull the cell string towards the top elongated protective sheet 200A and keep them flat against the semi-cured front support material for CIGS solar cells fabricated on magnetic stainless steel foils such as the #430 stainless steel. With the magnets in place, the back support silicon material may be dispensed over the cell strings to cover the back side of the cells. With the magnets still in place, the silicone may be heated to be partially or fully cured. This way the cells may be trapped in between two layers of partially or fully cured silicone layers. Then the magnets may be removed, the back elongated protective sheet 200B may be placed on the moisture sealant 204 and the support material 210 to complete the formation of a continuous packaging structure 300 including a plurality of module structures. Partial curing of silicone may be achieved at a temperature range of 60-100° C.

Referring back to FIG. 4A, in order to eliminate air entrapment within the modules, the divider sealants 207 between the module structures 302 may have small cuts or holes so that as the continuous packaging structure 300 is laminated any air within a particular module structure 302, as it is transformed into a module between the rollers 450, passes into the next module structure through the uncured divider sealant between the two module structures. Since the next module is not laminated yet and thereby not sealed, entrapped air is released from this module structure and the divider sealant 207 with cuts or holes melts and heals these cuts and holes. Alternatively, to avoid air entrapment, the roll lamination may be carried out in a vacuum environment with pressure values in the order of milli-Torrs. Such vacuum levels can be obtained by building separately pumped chambers through which the continuous packaging structure 300 passes through to arrive to the chamber where the roll lamination process is carried out. For example, the continuous packaging structure may enter a first chamber through a narrow slit and then go in and out a number of chambers through narrow slits before arriving into the roll lamination chamber and then travel through several other chambers before exiting the system through a last chamber. This way the pressure may be changed from near atmospheric pressure (760 Torr) in the first and last chambers to a much lower value (such as 100 mTorr) in the lamination chamber.

FIG. 4B shows the continuous multi-module device 300A after the roll lamination process in top view wherein the light receiving side of the solar cells 213 is toward the paper plane. The continuous multi-module device 300A may be rolled into a receiving roll (not shown) with the electrical leads 214 or terminals of each module in the multi-module device protruding from the side of the receiving roll. This way the terminals do not interfere with the rolling process. The roll may be shipped for further processing or installation in the field. FIG. 4B shows the continuous multi-module device 300A obtained after the lamination and sealing process. Each of the modules 302A in this multi-module device is sealed against moisture transmission from outside environment into the module structure where the solar cell strings 212 are encapsulated.

The continuous process described above is very versatile. Once the continuous multi-module device is formed, this device may be used in a variety of ways. In one approach the continuous multi-module packaging device is cut into individual modules 302A along the dotted cut lines ‘A’ which are within the divider walls as shown in FIG. 4B, producing completely separate and sealed individual modules. The electrical leads 214 of each module 302A are on the side and does not get affected or cut by this process and the integrity of the moisture sealant 204 is not compromised anywhere along the perimeter of each module. Having electrical leads 214 come out the side along at least one of the two long edges 203 of the continuous multi-module device 302A also maximizes the active area of each module while keeping the integrity of the moisture sealant 204.

In another approach, the continuous multi-module device may be used to form monolithically integrated multi-module power supplies comprising two or more electrically interconnected modules on a common, uncut substrate or superstrate as will be described more fully below. FIG. 5 shows in side view an individual module 302A that is manufactured using the process of the present invention by cutting and separating each of the modules 302A from the continuous multi-module device 300A as shown in FIG. 4B. The solar cell string 212 is coated with the support material 210 and disposed between a top protective sheet 303A and a bottom protective sheet 303B. The top protective sheet 303A and the bottom protective sheet 303B are portions of the top and bottom elongated protective sheets 200A and 200B. The moisture sealant 204 extends between the protective sheets 303A and 300B and seals the perimeter of the module. As mentioned each solar cell 213 includes the front portion 215A or light receiving portion and the back portion 215B or base. As will be appreciated, in operation, sun light enters the module through the top protective sheet 303A and arrives at the front portion 215A of the solar cells through the support material 210. The base 215B includes a substrate and a contact layer formed on the substrate. A preferred substrate material may be a metallic material such as stainless steel, aluminum or the like. An exemplary contact layer material may be molybdenum. The front portion 215A of the solar cells may include an absorber layer 305, such as a CIGS absorber layer which is formed on the contact layer, and a transparent layer 306, such as a buffer-layer/ZnO stack, formed on the absorber layer. An exemplary buffer layer may be a (Cd,Zn)S layer. Conductive fingers 308 may be formed over the transparent layer. Conductive leads 310 electrically connect the substrate or the contact layer of one of the solar cells to the transparent layer of the next solar cell. However, the solar cells may be interconnected using any other method known in the field such as shingling.

The front protective sheet 200A may be a transparent flexible polymer film such as TEFZEL®, or another polymeric film. The front protective sheet 200A comprises a transparent moisture barrier coating which may comprise transparent inorganic materials such as alumina, alumina silicates, silicates, nitrides etc. TEDLAR® and TEFZEL® are brand names of fluoropolymer materials from DuPont. TEDLAR® is polyvinyl fluoride (PVF), and TEFZEL® is ethylene tetrafluoroethylene (ETFE) fluoropolymer. The back protective sheet 200B may be a polymeric sheet such as TEDLAR®, or another polymeric material which may or may not be transparent. The back protective sheet may comprise stacked sheets comprising various material combinations such as metallic films as moisture barrier.

As stated before, one advantage of the present invention is its versatility. Instead of cutting and separating each of the modules 302A from the continuous multi-module device 300A shown in FIG. 4B, the cutting operation may be performed to form monolithically integrated multi-module power supplies with power ratings much in excess of what is the norm today. Typical high wattage modules in the market have power ratings in the range of 200-300 W. These are structures fabricated using standard methods by interconnecting all solar cells and strings within the module structure. With the light weight and flexible structures of the present invention it is feasible to construct monolithically integrated multi-module power supplies with ratings of 600 W and over and even with power ratings of over 1000 W. A roll of a flexible and light weight power generator with multi kW rating on a single substrate can enable new applications in large scale solar power fields. It should be noted that, using the teachings of the present inventions it is possible to build a single module of multi kW rating (such as 2000-5000 W), the single module having one moisture sealant in the form of a moisture barrier frame around its perimeter (see, for example, FIG. 2A). However, manufacturing monolithically integrated multi-module power supplies comprising many individual modules each having its own moisture impermeable or moisture resistant structure has many advantages. One advantage is better reliability in such multi-module devices. If any moisture enters into any of the individual modules of the monolithically integrated flexible multi-module power supply due to a failure of the top protective sheet, the bottom protective sheet or side sealant at that module location, the moisture would not be able to travel through to other modules because of the presence of divider sealants or divider walls. Therefore, the rest of the monolithically integrated multi-module power supply would continue producing power. Another advantage is the application flexibility offered by the method of manufacturing described above. As discussed before, the continuous multi-module device 300A shown in FIG. 4B may be cut into single module structures for applications that require low wattage (100-600 W). For large rooftop applications, the continuous multi-module device may be cut to include 5-10 modules and therefore provide a monolithically integrated multi-module power supply with a rating in the range of, for example, 500-2000 W. For very large power field applications, multi-module power supplies with power ratings of 1000-20000 W or higher may be employed. The important point is that all of these products can be manufactured from the same manufacturing line by just changing the steps of cutting. Presence of divider sealants between unit modules makes this possible. If divider sealants were not present, long and continuous module structures could not be cut into smaller units and be employed since moisture entering through the cut edges would limit the life of the cut modules or multi-module structures to much less than 20 years. For example, CIGS modules without a proper edge sealant would have a life of only a few years before loosing almost 50% of their power rating.

Certain advantages of the present invention may be demonstrated by an exemplary continuous multi-module device 500 shown in FIG. 6A, which may be manufactured using the process of the present invention described above. The continuous multi-module device 500, including solar cell modules 502A-502J, shown in FIG. 6A may be a portion of a longer continuous structure. Each module includes a solar cell string 512 having interconnected solar cells 513 and the light receiving side of the solar cells 213 facing toward the paper plane. Electrical leads 514 or output wires from each module are positioned along the side of the continuous multi-module device 500 as in the manner shown in FIG. 6A. The modules are separated from one another by divider walls 503 of the moisture sealant.

As shown in FIG. 6B, when an exemplary section 504 including the modules 502A-502E is separated from the continuous multi-module device 500 as described above, output wires 514 are interconnected to provide a combined power output from the modules 502A-502E of the section 504. For example if the power rating of each module is 100 W and if the cut section contains 10 modules that are interconnected, the resulting monolithically integrated multi-module power supply is a continuous, single piece 1000W supply. If the cut section contains 20 modules a 2000W power supply would be obtained. As shown in FIG. 6B, the interconnection between modules of the monolithically integrated multi-module power supply may be a series interconnection where the (+) terminal of each module is connected to a (−) terminal of an adjacent module. It should be noted that individual modules in the monolithically integrated multi-module power supply may also be interconnected in parallel mode.

The monolithically integrated multi-module power supply design of FIG. 6B provides advantage for deployment in the field. One advantage is the simplicity of installing a flexible, single piece, high-power power supply in the field. Elimination of handling many individual modules, elimination of many individual installation structures are some of the advantages. Another advantage is the ease of eliminating a malfunctioning module in the monolithically integrated multi-module power supply. This is possible because the inter-module interconnection terminals are outside and accessible. In section 504, for example, if the module 502 malfunctions, instead of discarding the whole section 504, the module 502B would be taken out of the circuitry by disconnecting its wires and the remaining modules 502A, 502C, 502D and 502E would be left interconnected and thus continue providing full power. Bypass diodes and other balance of system components may also be connected to the monolithically integrated multi-module power supply terminals. Although the cell strings in each module are shown to be parallel to the long edge of the monolithically integrated multi-module power supply shown in FIGS. 6A and 6B, cell strings may actually be placed in different directions in the module structure. For example, by placing cell strings perpendicular to the long edge of the monolithically integrated multi-module power supply one can reduce the length of each module (defined by the distance between the divider sealants or walls) compared to its width. This way the length of the wires used to interconnect the adjacent modules would be minimized to save cost and power loss in the interconnection wires and other hardware.

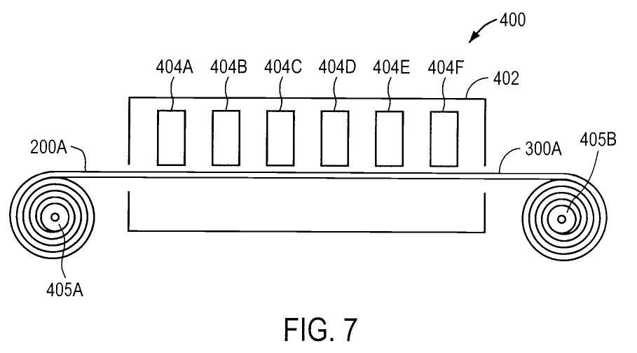

FIG. 7 shows a roll to roll system 400 to manufacture the continuous multi-module device 300A shown in FIGS. 3A-4B. The system 400 includes a process station 402 including a number of process units 404A-404F to perform above described process steps as the top protection layer 200A is supplied from the supply roll 405A and advanced through the process station 402. After processed in the lamination unit, the continuous packaging structure 300 is picked up and wrapped around the receiving roll 405B. In the following step the receiving roll 405B is taken into a cutting station to cut the continuous packaging structure 300A. In an alternative system without the receiving roll, the laminated continuous packaging structure 300 may be directly advanced into a cutting station and cut into individual modules or into monolithically integrated multi-module power supplies.

Although aspects and advantages of the present inventions are described herein with respect to certain preferred embodiments, modifications of the preferred embodiments will be apparent to those skilled in the art.

I claim:

1. A method of manufacturing a continuous multi-module power supply including a plurality of solar cell modules, comprising the steps of:
providing a first elongated protective sheet including a plurality of designated module areas, which are located in an end-to-end fashion;
applying a moisture barrier frame on the first elongated protective sheet surrounding the borders of the plurality of designated module areas, wherein the moisture barrier frame includes side walls disposed along the sides of the designated module areas and divider walls disposed between the adjacent designated module areas, wherein the first protective sheet, the side walls and the divider walls define a plurality of cavities;
placing a solar cell string into each cavity, the solar cell string comprising two or more solar cells that are electrically interconnected and include a front light receiving side facing the first elongated protection sheet and a back substrate side;
arranging two terminal wires with positive and negative polarity, with one end of each of the two terminal wires electrically connected to the solar cell string, and each of the two terminal wires extending through the moisture barrier frame so that another end of each of the two terminal wires extends outside the cavity and the moisture barrier frame;
at least partially covering each of the solar cell strings with a support material on both the front light receiving side and the back substrate side; and
placing a second elongated protective sheet over the support material and the moisture barrier frame to enclose the plurality of cavities, thereby forming a continuous elongated packaging structure including a plurality of solar cell modules.

2. The method of claim 1 wherein the step of arranging arranges the two terminal wires such that each of the two terminal wires extends through at least one of the side walls of the moisture barrier frame.

3. The method of claim 2 further comprising applying heat and pressure to the continuous elongated packaging structure with the solar cell modules to form a continuous multi-module device including a plurality of laminated solar cell modules that each have the two terminal wires that extend outside the side wall.

4. The method of claim 3, wherein the step of applying heat and pressure is performed while the continuous elongated package is rolled between rollers and is thereby transformed into the continuous multi-module device.

5. The method of claim 4 wherein the process of rolling is performed in a vacuum environment.

6. The method of claim 4, further comprising cutting the continuous multi-module device into sections, each section comprising one or more laminated solar cell modules wherein the step of cutting includes cutting through the divider walls between the laminated solar cell modules.

7. The method of claim 6, further comprising serially electrically connecting the laminated solar cell modules within each section to form monolithically integrated multi-module power supplies.

8. The method of claim 4, further including forming holes through the divider walls of the moisture barrier frame so as to allow the removal of entrapped air from the solar cell modules as the continuous elongated package is rolled between rollers.

9. A continuous multi-module power supply including a plurality of solar cell modules, comprising:
a first elongated protective sheet having elongated edges and short edges and a second elongated protective sheet having elongated edges and short edges, at least the first elongated protective sheet being made of a light-transparent material;
at least two solar cell strings disposed between the first and second elongated protective sheets, each of the at least two solar cell strings comprising two or more solar cells that are electrically interconnected, and wherein each solar cell string includes a front side facing the first elongated protective sheet and a back side facing the second elongated protective sheet;
a moisture barrier frame formed of a sealant disposed between the first and second protective sheets, wherein an edge of the moisture barrier frame is disposed between the first and second protective sheets and along the elongated and short edges at the perimeters thereof, and a divider of the moisture barrier frame is disposed between the first and second protective sheets and between each of the at least two solar cell strings;
a support material that fills the moisture barrier frame and covers the front and back sides of the at least two solar cell strings in the moisture barrier frame thus forming at least two solar cell modules; and
two terminal wires having positive and negative polarity connected to each of the at least two solar cell strings, wherein, for each of the at least two solar cell strings, one end of each of the two terminal wires is electrically connected to the solar cell string, each of the two terminal wires extend through the sealant so that another end of each of the two terminal wires extends outside the sealant.

10. The continuous multi-module power supply of claim 9 further including an interconnection wire disposed outside the at least two solar cell modules to electrically connect together some of the terminal wires.

11. The continuous multi-module power supply of claim 9, wherein the other end of each of the two terminal wires extends outside the sealant by passing through the elongated edge of the moisture barrier frame between some of the elongated edges of the first and second protective sheets.

12. The continuous multi-module power supply of claim 11, wherein the support material is a transparent polymeric material.

13. The continuous multi-module power supply of claim 11, wherein the first elongated protective sheet includes a moisture barrier flexible polymeric film

14. The continuous multi-module power supply of claim 13, wherein the second elongated protective sheet includes a moisture barrier flexible polymeric film.

15. The continuous multi-module power supply of claim 11, wherein the at least two solar cell strings each include Group IBIIIAVIA thin film solar cells.

16. The continuous multi-module power supply of claim 11 wherein the at least two solar cell strings, the front protective sheet and the back protective sheet are flexible.
